(19) United States
(12) Patent Application Publication
(10) Pub. No.: US 2008/0036394 A1
(43) Pub. Date: Feb. 14, 2008

(54) CURRENT SENSING TRANSFORMER, METHOD OF MANUFACTURING CURRENT SENSING TRANSFORMER, LAMP POWER SUPPLY HAVING THE CURRENT SENSING TRANSFORMER, AND LIQUID CRYSTAL DISPLAY HAVING THE LAMP POWER SUPPLY

(75) Inventor: Myoung Soo Kim, Gimhae-Si (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD., Suwon-Si (KR)

(21) Appl. No.: 11/836,243

(22) Filed: Aug. 9, 2007

(30) Foreign Application Priority Data
Aug. 9, 2006 (KR) 10-2006-0075300
Jul. 20, 2007 (KR) 10-2007-0073001

(51) Int. Cl. H05B 41/24; G01R 19/00; H01F 7/06

(52) U.S. Cl. 315/282; 29/605; 324/76.11

(57) ABSTRACT

The present invention relates to a current sensing transformer, a method of manufacturing the same, a lamp power supply having the same, and a liquid crystal display (“LCD”) having the lamp power supply, where the current sensing transformer includes a printed circuit board (“PCB”) having an insulating base plate, a first winding pattern formed in a predetermined shape on a first surface of the insulating base plate of the PCB, and a second winding pattern formed in a predetermined shape on a second surface, opposite the first surface, of the insulating base plate of the PCB.

This application claims priority to Korean Patent application Nos. 10-2006-0075300, filed on Aug. 9, 2006 & 10-2007-0073001, filed on Jul. 20, 2007, and all the benefits accruing therefrom under 35 U.S.C. §119, the contents of which in its entirety are herein incorporated by reference.

### BACKGROUND OF THE INVENTION

1. Field of the Invention

The present invention relates to a current sensing transformer, a method of manufacturing the same, a lamp power supply having the same, and a liquid crystal display (“LCD”) having the lamp power supply. More specifically, the present invention relates to a current sensing transformer reducing the number of components of a lamp power supply, a method of manufacturing the current sensing transformer, a lamp power supply having the current sensing transformer, and an LCD having the lamp power supply.

2. Description of the Related Art

A liquid crystal display (“LCD”) is used to adjust an amount of light transmitted in accordance with image signals applied to a number of control switches arrayed in a matrix form to display desired images on an LCD panel. The LCD includes an LCD panel on which images are displayed directly and a backlight unit that irradiates light on the LCD panel. Since such an LCD is not self-luminescent, a light source such as a backlight is required. A variety of fluorescent lamps, light emitting diodes (“LEDs”) and the like are used as light sources, and cold cathode fluorescent lamps (“CCFLs”) are mainly used. Recently, features such as large size and high brightness have been continuously required in LCDs through various applications such as LCD TVs and monitors. Accordingly, the number of lamps used as light sources in a backlight has been increased. Since the increase in the number of lamps results in a larger size of a lamp power supply required for lamp driving and a cost increase, techniques for cost reduction have been suggested.

A related art lamp power supply, i.e. a lamp-driving inverter unit, has been used to provide a high-voltage AC power to a lamp, and an additional current sensing transformer for sensing the level of power applied to the lamp has been required in addition to a transformer for transforming the level of AC power. As a result, since the number of components of the lamp power supply is increased, the production costs are increased accordingly. Further, as the size of the lamp power supply becomes large, a space required for mounting the lamp power supply within an LCD is increased.

### BRIEF SUMMARY OF THE INVENTION

The present invention reduces the production cost of a liquid crystal display is (“LCD”) and miniaturizes the size of a lamp power supply by reducing the number of components of the lamp power supply required for the lamp driving and simplifying a manufacturing process.

Accordingly, the present invention provides a coreless current sensing transformer manufactured using a printed circuit board (“PCB”) to reduce the number of components of a lamp power supply and to simplify a manufacturing process, a method of manufacturing the coreless current sensing transformer, a lamp power supply having the coreless current sensing transformer, and an LCD having the lamp power supply.

According to exemplary embodiments of the present invention, there is provided a current sensing transformer including a PCB having an insulating base plate, a first winding pattern formed in a predetermined shape on a first surface of the insulating base plate of the PCB, and a second winding pattern formed in a predetermined shape on a second surface of the insulating base plate of the PCB.

Preferably, the first and second winding patterns are arranged to face each other, and each of the first and second winding patterns is made of a conductive material, such as copper. Each of the first and second winding patterns may be shaped into any one of a polygon, a circle, and an ellipse.

The current sensing transformer may further include a first magnetic flux leakage prevention layer positioned on the first surface of the insulating base plate of the PCB and within the first winding pattern, and a second magnetic flux leakage prevention layer positioned on the second surface of the insulating base plate of the PCB and within the second winding pattern. Preferably, each of the first and second magnetic flux leakage prevention layers is made of a ferrite polymer composite. The first and second magnetic flux leakage prevention layers may be shaped to correspond to the first and second winding patterns, respectively.

Preferably, the PCB is a double-sided or multi-layered PCB.

According to other exemplary embodiments of the present invention a method of manufacturing a current sensing transformer includes providing a PCB, forming first and second winding patterns with a predetermined shape on first and second opposing surfaces of the PCB, respectively, and forming first and second magnetic flux leakage prevention layers within the first and second winding patterns, respectively.

Providing a PCB may further include providing a copper clad laminate with copper clad layers formed on first and second surfaces of an insulating base plate. Forming first and second winding patterns may further include forming photoresist patterns with a predetermined shape on the copper clad layers, etching the copper clad layers, and removing the photoresist patterns.

Preferably, each of the first and second magnetic flux leakage prevention layers may be made of a ferrite polymer composite.

According to further exemplary embodiments of the present invention, a lamp power supply includes a DC/AC converter converting DC power supplied from an outside into AC power, a transformer transforming a level of AC power output from the DC/AC converter, a power sensing unit sensing a level of AC power applied to a lamp, a comparator comparing a power level sensed by the power sensing unit to a reference power level to determine a change in power, and a controller controlling an operation of the DC/AC converter in response to a signal output from the comparator, wherein the power sensing unit includes a current sensing transformer including a PCB having an insulating base plate, a first winding pattern formed in a predetermined shape on a first surface of the insulating base plate of the PCB, and a second winding pattern formed in a predetermined shape on a second surface, opposite the first surface of the insulating base plate of the PCB.

The power sensing unit may further include a first magnetic flux leakage prevention layer positioned on the first surface of the insulating base plate of the PCB and within the first winding pattern, and a second magnetic flux leakage prevention layer positioned on the second surface of the insulating base plate of the PCB and within the second winding pattern.

Preferably, the DC/AC converter, the transformer that transforms a level of AC power output from the DC/AC converter, the comparator, and the controller are mounted on the PCB.

Preferably, the power sensing unit is connected to an input or output terminal of the transformer that transforms a level of AC power output from the DC/AC converter.

The lamp power supply may further include a switching unit connected to an input terminal of the DC/AC converter to control output of DC power supplied from the outside.

According to still further exemplary embodiments of the present invention, an LCD includes at least one lamp, a backlight unit including a lamp power supply which includes a DC/AC converter converting DC power supplied from outside into AC power, a transformer transforming a level of AC power output from the DC/AC converter, a power sensing unit sensing the level of AC power applied to the lamp, a comparator comparing a power level sensed by the power sensing unit to a reference power level to determine a change in power, and a controller controlling an operation of the DC/AC converter in response to a signal output from the comparator, and an LCD panel positioned above the backlight unit to display an image thereon, wherein the power sensing unit includes a current sensing transformer which includes a PCB having an insulating base plate, a first winding pattern formed in a predetermined shape on a first surface of the insulating base plate of the PCB, and a second winding pattern formed in a predetermined shape on a second surface, opposite the first surface, of the insulating base plate of the PCB.

### BRIEF DESCRIPTION OF THE DRAWINGS

The above and other features and advantages of the present invention will become apparent from the following description of preferred embodiments given in conjunction with the accompanying drawings, in which:

FIGS. 1A to 1C are perspective, plan, and sectional views of an exemplary current sensing transformer according to a first exemplary embodiment of the present invention, respectively;

FIGS. 2A and 2B are perspective views showing modified examples of the exemplary current sensing transformer according to the first exemplary embodiment of the present invention;

FIGS. 3A to 3C are perspective, plan, and sectional views of an exemplary current sensing transformer according to a second exemplary embodiment of the present invention, respectively;

FIGS. 4A to 4E are sectional views illustrating an exemplary process of manufacturing an exemplary current sensing transformer according to the present invention;

FIG. 5A is block diagram schematically showing an exemplary lamp power supply having an exemplary current sensing transformer according to the present invention, FIG. 5B is a circuit diagram schematically showing a power sensing unit and FIG. 5C is a perspective view of the current sensing transformer shown in FIG. 5B;

FIG. 6 is a schematic view showing a configuration of an exemplary DC/AC converter shown in FIG. 5A; and

FIG. 7 is an exploded perspective view of an exemplary liquid crystal display (“LCD”) having an exemplary lamp power supply according to the present invention.

### DETAILED DESCRIPTION OF THE INVENTION

The invention will now be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, preferred exemplary embodiments of the present invention will be further described with reference to the accompanying drawings.

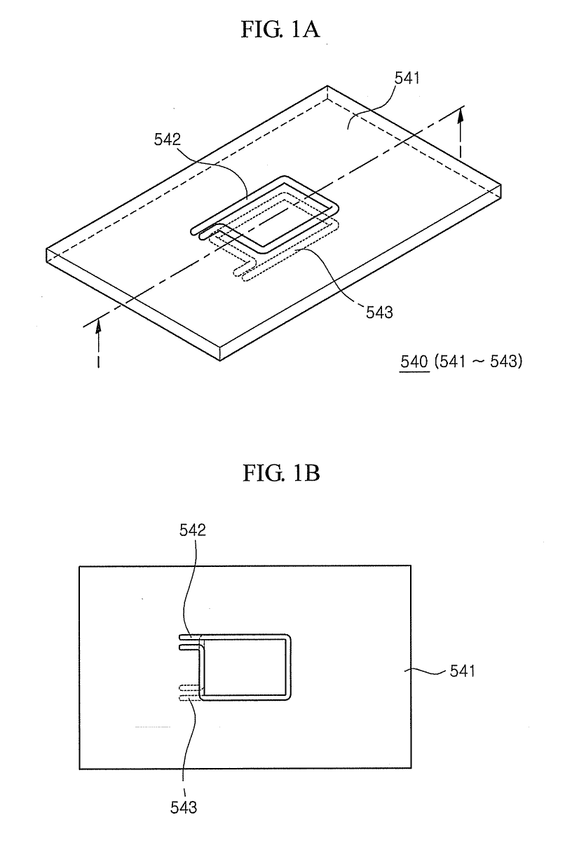

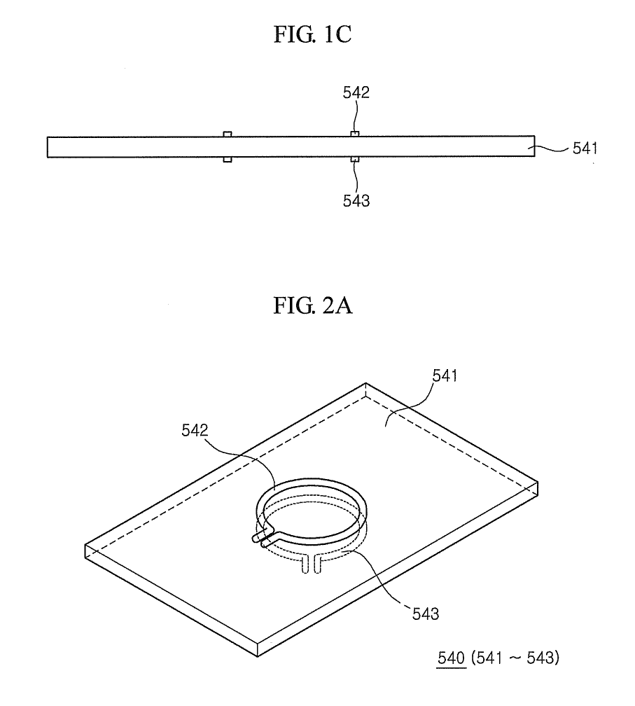

FIGS. 1A to 1C are perspective, plan, and sectional views of an exemplary current sensing transformer according to a first exemplary embodiment of the present invention, respectively.

Referring to FIGS. 1A to 1C, the current sensing transformer 540 includes an insulating base plate 541 of a printed circuit board (“PCB”), and first and second winding patterns 542 and 543.

The first winding pattern 542 is formed on one surface, i.e. a top surface of the insulating base plate 541 of the PCB, and the second winding pattern 543 is formed on the other surface, i.e. a bottom surface of the insulating base plate 541 of the PCB.

In general, a PCB is manufactured by forming a conductor pattern of a conductive material on either a surface of an insulating base plate or the surface and interior of the insulating base plate on the basis of a desired electrical design. The PCB serves as a support used to mount various kinds of components within a finished product and performs a function of connecting signals of the respective components to one another. Such a PCB is classified into a single-sided PCB with circuits formed on a single surface thereof, a double-sided PCB with circuits formed on both top and bottom surfaces thereof, a multi-layered PCB with circuits additionally formed within the interior of the PCB in addition to both the top and bottom surfaces thereof, and the like. Although the double-sided PCB is described as an example in this embodiment, the present invention is not limited thereto. That is, the multi-layered PCB may be used.

The first and second winding patterns 542 and 543 are formed substantially in the shape of a rectangle and are arranged to face each other. Further, each of the first and second winding patterns 542 and 543 is made of a conductive material. Preferably, each of the first and second winding patterns 542 and 543 is made of copper, which is generally used as an electrical conductive material in a PCB.

Although each of the first and second winding patterns 542 and 543 is wound once in this embodiment, the present invention is not limited thereto. That is, the number of windings of each of the first and second winding patterns 542 and 543 may vary. At this time, in a case where each of the first and second winding patterns 542 and 543 is wound at least twice or more, the first or second winding pattern 542 or 543 is spirally formed as a whole.

A related art current sensing transformer, not shown, is formed by winding first and second windings around a core. The first and second windings wound around the core are electrically isolated from but magnetically combined with each other. Thus, if an AC current flows into the first winding, magnetic flux passing through the core is changed and thus an induced electromotive force is generated in the second winding due to an electromagnetic induction action. Accordingly, the current sensing transformer senses a current using such a principle.

In the current sensing transformer 540 according to the present invention which includes first and second winding patterns 542, 543 corresponding respectively to the first and second windings of the related art current sensing transformer, if an AC current is applied to the first winding pattern 542, an induced electromotive force is generated in the second winding pattern 543 due to an electromagnetic induction action such that the current sensing transformer 540 can sense a current. Since the first and second winding patterns 542, 543 are not wound around a core, the current sensing transformer 540 is a coreless current sensing transformer.

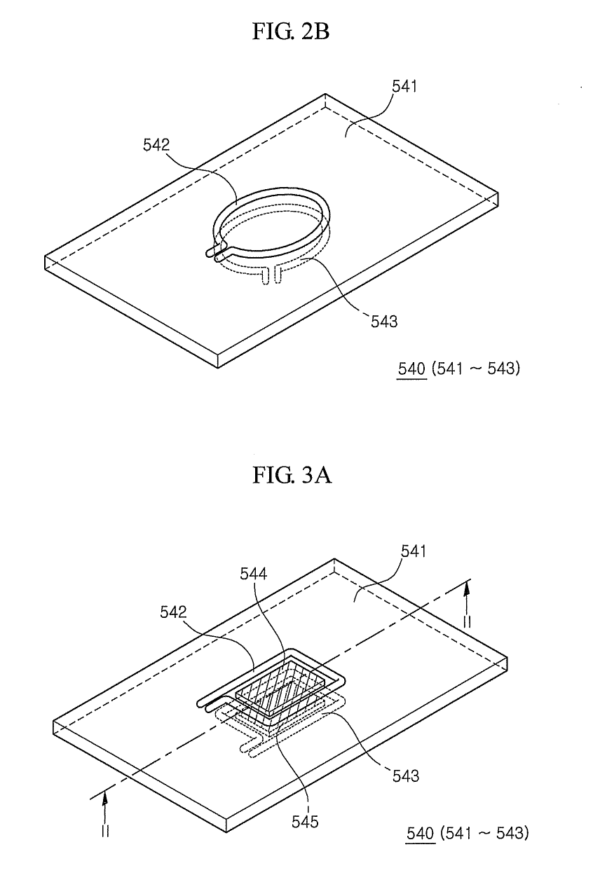

FIGS. 2A and 2B are perspective views showing modified examples of the exemplary current sensing transformer according to the first exemplary embodiment of the present invention.

Referring to FIGS. 2A and 2B, a first winding pattern 542 is formed on one surface, i.e. a top surface of an insulating base plate 541 of a PCB, and a second winding pattern 543 is formed on the other surface, i.e. a bottom surface of the insulating base plate 541 thereof. At this time, a pair of the first and second winding patterns 542 and 543 are formed in the shape of either a circle or a substantially circular shape as shown in FIG. 2A or an ellipse or a substantially elliptical shape as shown in FIG. 2B and are arranged to face each other. However, the shapes of the first and second winding patterns 542 and 543 are not limited thereto but may be changed in various ways.

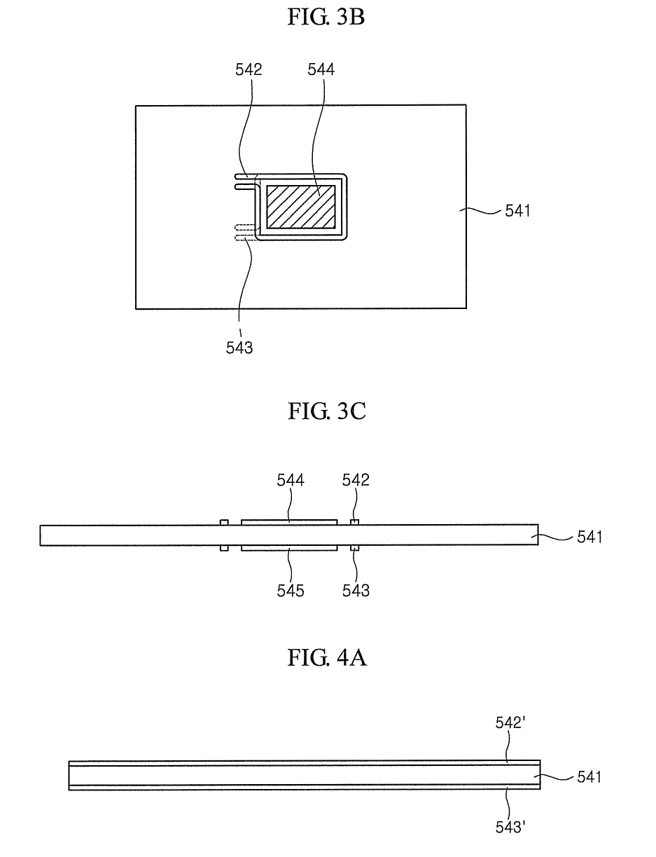

FIGS. 3A to 3C are perspective, plan, and sectional views of an exemplary current sensing transformer according to a second exemplary embodiment of the present invention, respectively.

Referring to FIGS. 3A to 3C, the current sensing transformer 540 comprises an insulating base plate 541 of a PCB, first and second winding patterns 542 and 543, and first and second magnetic flux leakage prevention layers 544 and 545.

The first winding pattern 542 is formed on one surface, i.e. a top surface of the insulating base plate 541 of the PCB, and the second winding pattern 543 is formed on the other surface, i.e. a bottom surface of the insulating base plate 541 thereof.

The first and second winding patterns 542 and 543 may be formed in the shape of a rectangle as illustrated and are arranged to face each other. Further, each of the first and second winding patterns 542 and 543 is made of a conductive material. Preferably, the winding pattern is made of copper, which is generally used as a conductive material in a PCB.

Although each of the first and second winding patterns 542 and 543 is wound once in this embodiment, the present invention is not limited thereto. That is, the number of windings of each of the first and second winding patterns 542 and 543 may vary. Further, the shapes of the first and second winding patterns 542 and 543 are not limited to the illustrated rectangle shape but the winding patterns may be formed into various shapes such as, but not limited to, a circle or ellipse as described above.

The first magnetic flux leakage prevention layer 544 is formed on one surface, i.e. the top surface of the insulating base plate 541 of the PCB and is preferably positioned within a space defined by the first winding pattern 542. Furthermore, the second magnetic flux leakage prevention layer 545 is formed on the other surface, i.e. the bottom surface of the insulating base plate 541 of the PCB and is preferably positioned within a space defined by the second winding pattern 543. The first and second magnetic flux leakage prevention layers 544 and 545 prevent magnetic flux generated between the first and second winding patterns 542 and 543 from leaking to the outside.

At this time, the first and second magnetic flux leakage prevention layers 544 and 545 are shaped to correspond to the shape of the first and second winding patterns 542 and 543, respectively. That is, each of the first and second magnetic flux leakage prevention layers 544 and 545 may be formed in the shape of a rectangle, however the first and second magnetic flux leakage prevention layers 544 and 545 may be formed in the shape of a circle, ellipse, or other shape defined by the first and second winding patterns 542 and 543.

Further, the first and second magnetic flux leakage prevention layers 544 and 545 are arranged such that they are spaced apart from the first and second winding patterns 542 and 543 by a predetermined interval, respectively. That is, the first and second winding patterns 542 and 543 are formed along the circumferences of the first and second magnetic flux leakage prevention layers 544 and 545, respectively. Also, the first and second winding patterns 542 and 543 may be spaced slightly from the circumferences of the first and second magnetic flux leakage prevention layers 544 and 545, respectively.

In addition, it is preferred that each of the first and second magnetic flux leakage prevention layers 544 and 545 be made of a ferrite polymer composite. Since the ferrite polymer composite is a composite of ferrite powder and plastic, it has a stable magnetic property and can be manufactured in the form of a flexible film. Therefore, a ferrite polymer composite is suitable for the magnetic flux leakage prevention layers 544, 545 of the exemplary embodiments of the present invention.

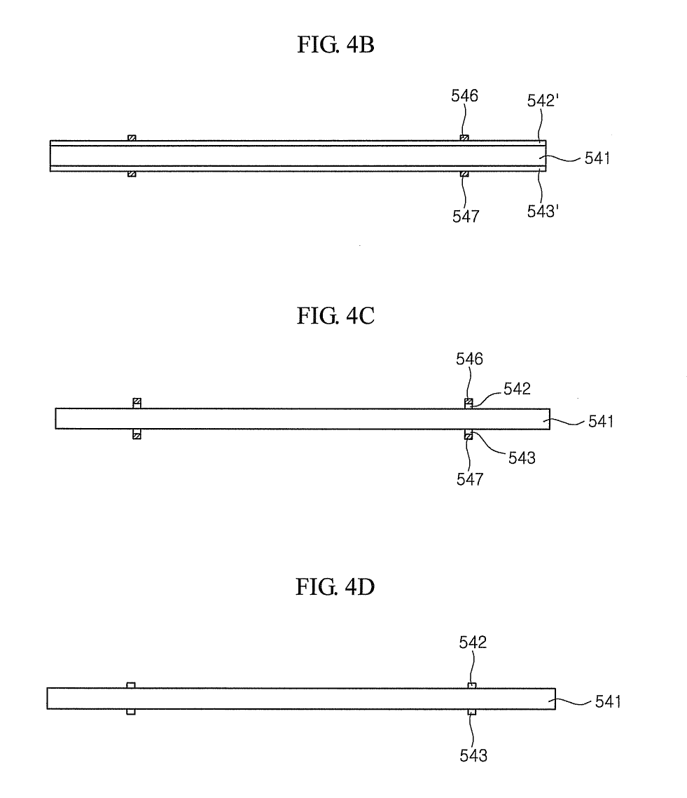

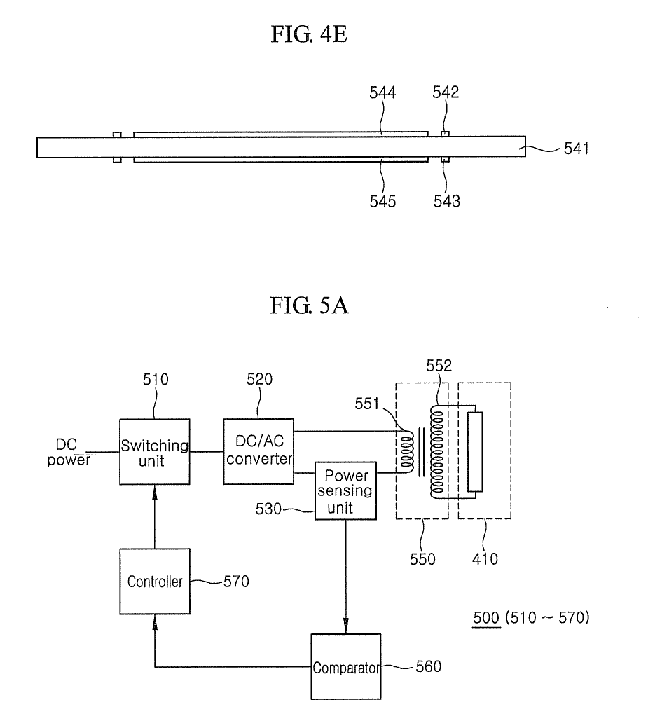

FIGS. 4A to 4E are sectional views illustrating an exemplary process of manufacturing an exemplary current sensing transformer according to the present invention.

Referring to FIG. 4A, a PCB is first provided. At this time, as the PCB is provided, a copper clad laminate with copper clad layers 542′ and 543′ formed on top and bottom surfaces of an insulating base plate 541 is provided. Although a copper clad laminate for a double-sided PCB is employed in this embodiment, the present invention is not limited thereto. A copper clad laminate for a multi-layered PCB may be employed.

Referring to FIG. 4B, photoresist patterns 546 and 547 with a predetermined shape are formed on the copper clad layers 542′ and 543′, respectively. To form the photoresist patterns 546 and 547, a photoresist may be formed on an entire surface of each of the copper clad layers 542′ and 543′ and then shaped into the predetermined photoresist patterns 546 and 547 through a light exposure and development process using a mask (not shown) with a predetermined pattern formed thereon.

Referring to FIGS. 4C and 4D, after the copper clad layers 542′ and 543′ have been etched using the photoresist patterns 546 and 547 as etching masks, the photoresist patterns 546 and 547 are removed to form first and second winding patterns 542 and 543 with a predetermined shape.

Referring to FIG. 4E, first and second magnetic flux leakage prevention layers 544 and 545 are formed within the first and second winding patterns 542 and 543, respectively. At this time, each of the first and second magnetic flux leakage prevention layers 544 and 545 may be formed by attaching a film made of a ferrite polymer composite to the insulating base plate 541 within the peripheries of the first and second winding patterns 542 and 543. Instead of attaching a film t the plate 541, the magnetic flux leakage prevention layers 544 and 545 may alternatively be formed by performing a photolithography and etching process on a thin film formed on the plate 541. However, the present invention is not limited thereto, but the material, shape and manufacturing process of the first and second magnetic flux leakage prevention layers 544 and 545 may be changed in various ways. Further, while it has been described in this embodiment that a winding pattern 542 or 543 is first formed and then a magnetic flux leakage prevention layer 544 or 545 is formed within the winding pattern, in an alternative embodiment, a magnetic flux leakage prevention layer 544 or 545 may first be formed and then a winding pattern 542 or 543 surrounding the layer 544 or 545 may be formed.

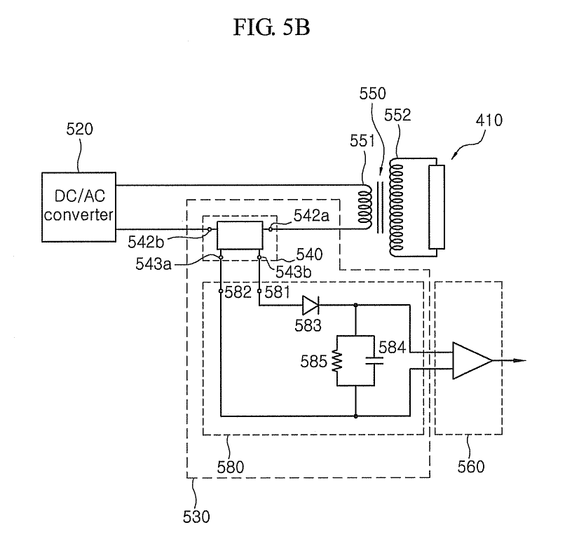

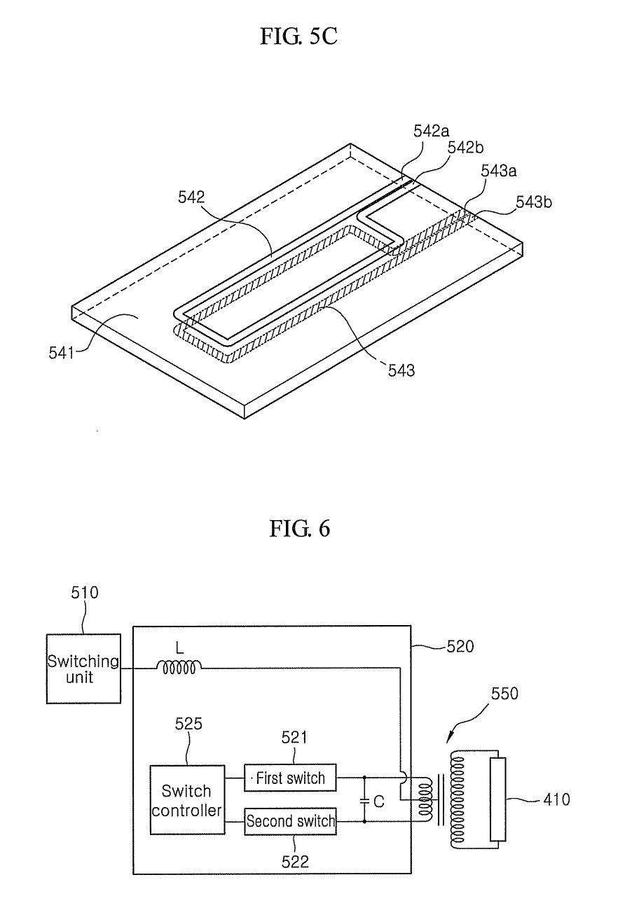

FIG. 5A is block diagram schematically showing an exemplary lamp power supply having an exemplary current sensing transformer according to the present invention, FIG. 5B is a circuit diagram schematically showing a power sensing unit and FIG. 5C is a perspective view of the current sensing transformer shown in FIG. 5B. FIG. 6 is a schematic view showing the configuration of an exemplary DC/AC converter shown in FIG. 5A.

Referring to FIGS. 5A to 6, the lamp power supply 500 includes a switching unit 510, a DC/AC converter 520, a power sensing unit 530, a transformer 550, a comparator 560, and a controller 570.

The switching unit 510 controls the output of DC power supplied from the outside. The DC/AC converter 520 connected to an output terminal of the switching unit 510 converts DC power supplied through the switching unit 510 into AC power.

The DC/AC converter 520 includes an inductor L, a capacitor C, first and second switches 521 and 522, and a switch controller 525. The capacitor C is connected in parallel to the transformer 550, wherein a first node of the capacitor C is connected to the first switch 521 and a second node thereof is connected to the second switch 522.

The transformer 550 is connected to an output terminal of the DC/AC converter 520. Further, the transformer 550 transforms the level of an AC power output from the DC/AC converter 520 to provide the transformed AC power to a lamp 410 as shown in FIGS. 5 and 6, so that the lamp 410 can be driven. A first winding 551 of the transformer 550 is connected to the output terminal of the DC/AC converter 520, and may be further connected to the power sensing unit 530 as will be further described below. A second winding 552 of the transformer 550 is connected to both electrodes of the lamp 410.

The power sensing unit 530 performs a function of sensing the level of the AC power applied to the lamp 410. In this embodiment, the power sensing unit 530 includes the aforementioned current sensing transformer 540 using a PCB, and a current change detection unit 580. Further, the power sensing unit 530 including the current sensing transformer 540 can be connected to the first winding 551 of the transformer 550 to sense a current applied to the lamp 410, as described in this embodiment of the present invention. Alternatively, the power sensing unit 530 may be connected to the second winding 552 of the transformer 550 to sense a current applied to the lamp 410.

The comparator 560 determines if a level of current change detected by the current change detection unit 580 is in a normal state, and the controller 570 turns on/off the switching unit 510 in response to signals output from the comparator 560 to control the operation of the DC/AC converter 520.

Referring to FIGS. 5B and 5C, a circuit configuration and operation scheme of the power sensing unit 530 and the comparator 560 will be described. The power sensing unit 530 includes a current sensing transformer 540 and a current change detection unit 580.

The current sensing transformer 540 includes an insulating base plate 541 on a printed circuit board, a first winding pattern 542 formed on one side of the insulating base plate 541 and a second winding pattern 543 on the other side of the insulating base plate 541. First connection terminals 542a and 542b are formed at both ends of the first winding pattern 542, and second connection terminals 543a and 543b are formed at both ends of the second winding pattern 543.

The first winding pattern 542 of the current sensing transformer 540 is connected between a first winding 551 of a transformer 550 and a DC/AC converter 520. That is, one of the first connection terminals 542a of the first winding pattern 542 is connected to the first winding 551, and the other one of the first connection terminals 542b is connected to the DC/AC converter 520. Further, the second winding pattern 543 is connected to the current change detection unit 580. That is, the second connection terminals 543a and 543b of the second winding pattern 543 are connected to detection terminals 581 and 582 of the current change detection unit 580

The current sensing transformer 540 detects a current change by sensing a magnetic flux change Δφ in the first winding pattern 542 connected to the first winding 551 of the transformer 550. The current sensing transformer 540 includes the second winding pattern 543.

The detection terminal 581 and 582 of the current change detection unit 580 is connected to the second connection terminal 543a and 543b of the second winding pattern 543, and detects a voltage generated due to the magnetic flux change Δφ. The voltage detected at the detection terminal 581 and 582 is supplied to a circuit which detects a current change. Such a circuit includes a diode 583, a condenser 584 and resistor 585. The diode 583 is connected to the detection terminal 581. The condenser 584 and the resistor 585 are connected between a cathode and the detection terminal 582 of the diode 583 as a filtering circuit. As such, the current change detection unit 580 is configured as a current/voltage converter which converts the current change to the change of DC voltage, thereby the condenser 584 and the resistor 585 obtain a DC voltage in response to the current change. The level of DC voltage indicates the current change.

The detected signal by the current change detection unit 580 is supplied to the comparator 560. The comparator 560 is included in an amplifier of the detected signal, and determines if the operation is in normal state by comparing the level of current change. The controller 570 turns on/off the switching unit 510 in response to signals output from the comparator 560 to control the operation of the DC/AC converter 520.

An operation of the lamp power supply will now be described. If the switching unit 510 is turned on, a DC power from the outside is applied to the DC/AC converter 520 through the switching unit 510, and an AC voltage, e.g. a sine wave voltage, is applied throughout a load or lamp from the DC/AC converter 520. A current flows into the center tap of the transformer 550 via the inductor L. The switch controller 525 controls the turning on/off of the first and second switches 521 and 522, and the first and second switches 521 and 522 are alternately opened and closed to generate an AC waveform throughout the second winding 552 of the transformer 550. At this time, although the operating frequencies of the first and second switches 521 and 522 may be fixed, they are normally synchronized with the resonance frequency of a reactance element (i.e., capacitor C) of a circuit. If the operating frequencies of the first and second switches 521 and 522 are synchronized with the resonance frequency of the reactance element of the circuit, a sine wave is output.

If the switching unit 510 is turned off, a DC power supplied to the lamp power supply is cut off and the switching unit 510 adjusts the DC power output by means of the output of the controller 570 to control the power applied to the lamp 410.

The power sensing unit 530 is connected to the first or second winding 551 or 552 of the transformer 550, so that it can be determined based on the current sensed by the power sensing unit 530 whether current is normally supplied to the lamp 410 from the DC/AC converter 520.

At this time, the power sensing unit 530 includes the current sensing transformer 540 which includes the insulating base plate 541 of the PCB, the first and second winding patterns 542 and 543, and the first and second magnetic flux leakage prevention layers 544 and 545, as described above. The switching unit 510, the DC/AC converter 520, the transformer 550, the comparator 560, the controller 570 and the like, which are components of the aforementioned lamp power supply, may be mounted on the PCB with the current sensing transformer 540 formed thereon, in addition to the current sensing transformer 540.

Consequently, the present invention is configured in such a manner that a current sensing transformer is formed on a PCB, which is widely used in an LCD, so that it is not necessary to use an additional current sensing transformer as a separate component. Further, the number of components of a lamp power supply can be reduced and a manufacturing process can also be simplified using the current sensing transformer of the present invention. Accordingly, production costs of the lamp power supply can be reduced.

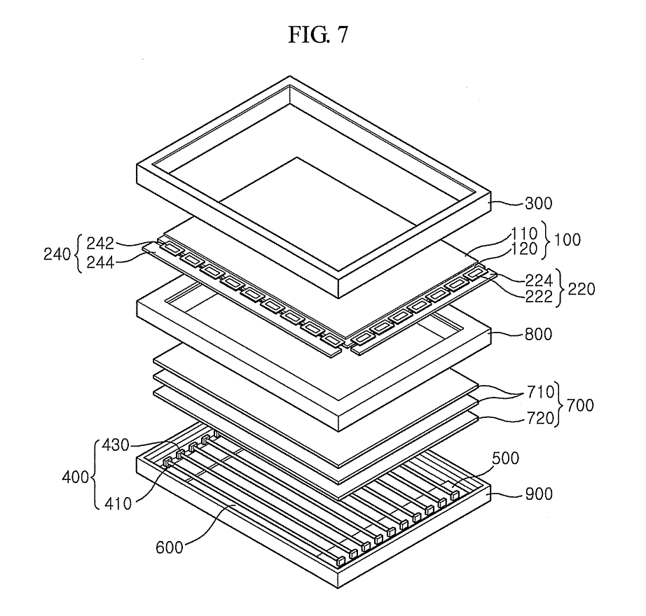

FIG. 7 is an exploded perspective view of an exemplary LCD having an exemplary lamp power supply according to the present invention.

Referring to FIG. 7, the LCD includes a top chassis 300, an LCD panel 100, driving circuit units 220 and 240, a lamp unit 400, a lamp power supply 500, optical members 700 including a plurality of optical sheets 710 and a diffusion plate 720, a mold frame 800, and a bottom chassis 900.

The LCD panel 100 includes a common electrode panel 110 and a TFT substrate 120. The driving circuit units 220 and 240 are connected to the LCD panel 100. The driving circuit units 220 and 240 include a gate-side PCB 224 equipped with a control integrated circuit (“IC”) to apply predetermined gate signals to gate lines of the TFT substrate 120, a data-side PCB 244 equipped with a control IC to apply predetermined data signals to data lines of the TFT substrate 120, a gate-side flexible PCB 222 for connecting the TFT substrate 120 and the gate-side PCB 224, and a data-side flexible PCB 242 for connecting the TFT substrate 120 and the data-side PCB 244.

The top chassis 300 is formed into a rectangular frame with planar and sidewall portions bent perpendicular to each other in order to prevent the LCD panel 100 and the driving circuit units 220 and 240 from being separated from the other elements of the LCD and to protect them against external impact.

The lamp unit 400 includes lamps 410 and lamp sockets 430 for seating the lamps 410 thereon.

To drive the lamps 410, the lamp power supply 500 functions to generate power applied to the lamps 410. At this time, the lamp power supply 500 is manufactured by mounting a switching unit, a DC/AC converter, a transformer, a comparator, a controller and the like, which are components of the lamp power supply 500, onto a PCB, as described above. Accordingly, since a current sensing transformer is further formed on a PCB on which a variety of components of a lamp power supply 500 will be mounted, it is not necessary to utilize an additional current sensing transformer as a separate component.

The plurality of optical sheets 710, the diffusion plate 720, the lamp unit 400 and the reflection plate 600 are sequentially stacked one above another on a bottom surface of a storage space defined in the mold frame 800. The bottom chassis 900 coupled with the mold frame 800 to hold the above components is positioned below the mold frame 800.

As described above, according to the present invention, a coreless current sensing transformer can be manufactured using a PCB with various components of a lamp power supply mounted thereon instead of employing an additional current sensing transformer as an additional component. Therefore, the number of components can be reduced and a manufacturing process can also be simplified.

Consequently, manufacturing costs of the lamp power supply and the LCD including the lamp power supply can be reduced.

The foregoing merely describes exemplary embodiments of a current sensing transformer, a method of manufacturing the same, a lamp power supply having the current sensing transformer, and an LCD having the lamp power supply according to the present invention. Thus, the present invention is not limited thereto. Although the present invention has been described in detail in connection with the preferred embodiments, it will be readily understood by those skilled in the art that various modifications and changes can be made thereto within the technical spirit and scope of the present invention. It is also apparent that the modifications and changes fall within the scope of the present invention defined by the appended claims.

What is claimed is:

1. A current sensing transformer comprising:
a printed circuit board having an insulating base plate;
a first winding pattern formed in a predetermined shape on a first surface of the insulating base plate of the printed circuit board; and
a second winding pattern formed in a predetermined shape on a second surface, opposite the first surface, of the insulating base plate of the printed circuit board.

2. The current sensing transformer as claimed in claim 1, wherein the first and second winding patterns are arranged to face each other.

3. The current sensing transformer as claimed in claim 1, wherein each of the first and second winding patterns is made of a conductive material.

4. The current sensing transformer as claimed in claim 3, wherein each of the first and second winding patterns comprises copper.

5. The current sensing transformer as claimed in claim 1, wherein each of the first and second winding patterns is shaped into one of a polygon, a circle, and an ellipse.

6. The current sensing transformer as claimed in claim 1, further comprising:
a first magnetic flux leakage prevention layer positioned on the first surface of the insulating base plate of the printed circuit board and within the first winding pattern; and
a second magnetic flux leakage prevention layer positioned on the second surface of the insulating base plate of the printed circuit board and within the second winding pattern.

7. The current sensing transformer as claimed in claim 6, wherein each of the first and second magnetic flux leakage prevention layers is made of a ferrite polymer composite.

8. The current sensing transformer as claimed in claim 6, wherein the first and second magnetic flux leakage prevention layers are shaped to correspond to the first and second winding patterns, respectively.

9. The current sensing transformer as claimed in claim 1, wherein the printed circuit board is a double-sided or multi-layered printed circuit board.

10. The current sensing transformer as claimed in claim 1, wherein the first winding pattern has substantially the same shape as the second winding pattern.

11. A method of manufacturing a current sensing transformer, the method comprising:
providing a printed circuit board;
forming first and second winding patterns with a predetermined shape on first and second opposing surfaces of the printed circuit board, respectively; and
forming first and second magnetic flux leakage prevention layers within the first and second winding patterns, respectively.

12. The method as claimed in claim 11, wherein providing a printed circuit board further comprises providing a copper clad laminate with copper clad layers formed on first and second surfaces of an insulating base plate.

13. The method as claimed in claim 12, wherein forming first and second winding patterns further comprises:
forming photoresist patterns with a predetermined shape on the copper clad layers;
etching the copper clad layers; and
removing the photoresist patterns.

14. The method as claimed in claim 11, wherein forming first and second magnetic flux leakage prevention layers comprises forming each of the first and second magnetic flux leakage prevention layers from a ferrite polymer composite.

15. A lamp power supply comprising:
a DC/AC converter converting DC power supplied from an outside source into AC power;
a transformer transforming a level of AC power output from the DC/AC converter;
a power sensing unit sensing a level of AC power applied to a lamp;
a comparator comparing a power level sensed by the power sensing unit with a reference power level and determining a change in power; and
a controller controlling an operation of the DC/AC converter in response to a signal output from the comparator,
wherein the power sensing unit includes a current sensing transformer which comprises a printed circuit board having an insulating base plate, a first winding pattern formed in a predetermined shape on a first surface of the insulating base plate of the printed circuit board, and a second winding pattern formed in a predetermined shape on a second surface, opposite the first surface, of the insulating base plate of the printed circuit board.

16. The lamp power supply as claimed in claim 15, wherein the power sensing unit further comprises a first magnetic flux leakage prevention layer positioned on the first surface of the insulating base plate of the printed circuit board and within the first winding pattern, and a second magnetic flux leakage prevention layer positioned on the second surface of the insulating base plate of the printed circuit board and within the second winding pattern.

17. The lamp power supply as claimed in claim 15, wherein the DC/AC converter, the transformer transforming a level of AC power output from the DC/AC converter, the comparator, and the controller are mounted on the printed circuit board.

18. The lamp power supply as claimed in claim 15, wherein the power sensing unit is connected to an input or output terminal of the transformer that transforms a level of AC power output from the DC/AC converter.

19. The lamp power supply as claimed in claim 15, further comprising a switching unit connected to an input terminal of the DC/AC converter to control output of DC power supplied from the outside.

20. A liquid crystal display comprising:
at least one lamp;
a backlight unit including a lamp power supply which comprises a DC/AC converter converting DC power supplied from outside into AC power, a transformer transforming a level of AC power output from the DC/AC converter, a power sensing unit sensing level of AC power applied to the at least one lamp, a comparator comparing a power level sensed by the power sensing unit with a reference power level to determine a change in power, and a controller controlling an operation of the DC/AC converter in response to a signal output from the comparator; and
a liquid crystal display panel positioned above the backlight unit to display an image thereon,
wherein the power sensing unit includes a current sensing transformer which comprises a printed circuit board having an insulating base plate, a first winding pattern formed in a predetermined shape on a first surface of the insulating base plate of the printed circuit board, and a second winding pattern formed in a predetermined shape on a second surface, opposite the first surface, of the insulating base plate of the printed circuit board.
